(19) United States
(12) Patent Application Publication
(10) Pub. No.: US 2025/0199071 A1
(43) Pub. Date: Jun. 19, 2025

(54) Sensor Assembly for a Switchgear Connector

(71) Applicants: TE Connectivity Solutions GmbH, Schaffhausen (CH); Tyco Electronics UK LTD, Swindon (GB)

(72) Inventors: Axel Winter, Ottobrunn (DE); Jonathan Roberts, Cambridge (GB); Stephen Wiseman, Cambridge (GB); Veronica Biagini, Ottobrunn (DE)

(73) Assignees: TE Connectivity Solutions GmbH, Schaffhausen (CH); Tyco Electronics UK LTD, Swindon (GB)

(21) Appl. No.: 18/980,368

(22) Filed: Dec. 13, 2024

(30) Foreign Application Priority Data
Dec. 14, 2023 (EP) 23216495.4

(51) Int. Cl. G01R 31/327; H02B 13/00

(52) U.S. Cl. CPC G01R 31/3274; H02B 13/00

(57) ABSTRACT

A sensor assembly for a switchgear connector includes a high voltage side facing a switchgear, a low voltage side, and an isolation barrier that provides a galvanic isolation between the high voltage side and the low voltage side. The sensor assembly includes a sensor device measuring at least one physical quantity and outputting a sensor data representative of the at least one physical quantity. The sensor device is arranged on the high voltage side. The sensor assembly includes a data interface arranged on the low voltage side and providing for the sensor data to be accessible from outside of the sensor assembly. The sensor assembly includes a transmission path transferring the sensor data between the sensor device and the data interface. The transmission path has a wireless section extending across the isolation barrier.

### CROSS-REFERENCE TO RELATED APPLICATIONS

This application claims the benefit of the filing date under 35 U.S.C. § 119(a)-(d) of European Patent Application No. EP 23216495.4, filed on Dec. 14, 2023.

### FIELD OF THE INVENTION

The invention relates to a sensor assembly for a switchgear connector, a back plug for a switchgear connector containing part of the sensor assembly, and a set for a switchgear connector comprising the back plug and a sensor unit.

### BACKGROUND OF THE INVENTION

Switchgear connectors are often used in medium and high voltage applications to connect switchgear and transformers. They are used in outdoor power distribution systems and/or indoor applications like in substations, and are required to perform under ambient conditions, which in some cases may be extreme. Reliable performance of these connectors is critical to ensure proper functioning of the electrical systems.

### SUMMARY OF THE INVENTION

A sensor assembly for a switchgear connector includes a high voltage side facing a switchgear, a low voltage side, and an isolation barrier that provides a galvanic isolation between the high voltage side and the low voltage side. The sensor assembly includes a sensor device measuring at least one physical quantity and outputting a sensor data representative of the at least one physical quantity. The sensor device is arranged on the high voltage side. The sensor assembly includes a data interface arranged on the low voltage side and providing for the sensor data to be accessible from outside of the sensor assembly. The sensor assembly includes a transmission path transferring the sensor data between the sensor device and the data interface. The transmission path has a wireless section extending across the isolation barrier.

### BRIEF DESCRIPTION OF THE DRAWINGS

The invention will now be described by way of example with reference to the accompanying figures, of which:

FIG. 1 is a schematic sectional view of a switchgear connector; and

FIG. 2 is a schematic block diagram of an embodiment of a sensor assembly contained in a back plug;

FIG. 3 is a schematic block diagram of an embodiment of a sensor assembly with slip rings;

FIG. 4 is a schematic block diagram of an embodiment of a sensor assembly with two locally separated parts of the sensor assembly;

FIG. 5 is a schematic block diagram of a capacitive voltage sensor; and

FIG. 6 is a schematic perspective view of a lug mounted sensor.

### DETAILED DESCRIPTION OF THE EMBODIMENT(S)

The invention shall be explained in more detail hereafter by way of example with reference to the drawings. The feature combinations illustrated in the embodiments shown by way of example can be supplemented by further features in correspondence with the properties of the invention required for a specific application. Individual features can also be omitted from the embodiments described if the effect of these features is of no relevance for a specific application. The same reference numerals in the drawings are used for elements having the same function and/or the same structure.

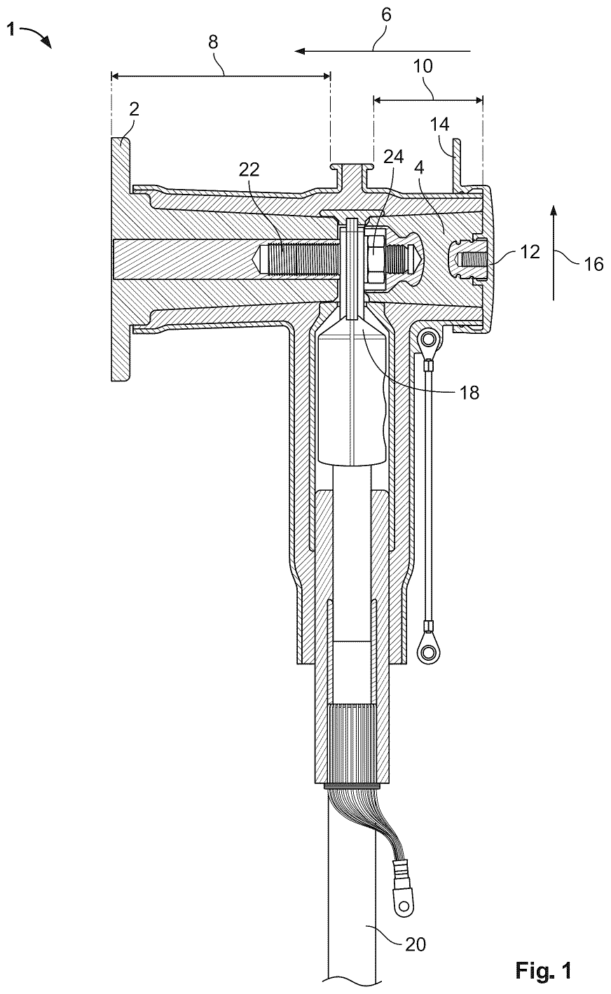

FIG. 1 shows a sectional view of a switchgear connector 1 which may be designed as an elbow connector with a horizontal or proximal part comprising a switchgear interface 2 and a back plug 4, that is inserted into the switchgear connector 1 from a side opposite the switchgear interface 2. The switchgear interface 2 is to be connected to a switchgear in a connection direction 6, in the same direction as the installation direction of the back plug 4. The horizontal part of the switchgear connector 1 may be cylindrical, whereas the switchgear interface 2 is located on the end of the horizontal part that is located on the side further along the direction of connection 6. The back plug 4 is depicted as a truncated cone. The switchgear interface 2 reaches into the switchgear connector 1 in the direction opposite to the connection direction 6 and is designed with a greater length 8 than a length 10 of the back plug 4. In another embodiment, the switchgear interface 2 and the back plug 4 can have the same length. Alternatively, the length 10 of the back plug 4 can be longer than the length 8 of the switchgear interface 2.

The switchgear connector 1 further comprises an end cap 12 that is placed onto the switchgear connector 1 after the back plug 2 is inserted. The end cap 12 can be shaped as a circle with a slightly greater diameter than the base of the cylindrical horizontal part of the switchgear connector 1. The end cap 12 can be shaped as a lid, having a circular border protruding from the circle in the connection direction 6 and designed in a way, so that the border of the end cap 12 lies flush against the circumference of the horizontal part of the switchgear connector 1, frictionally engaging with the circumference of the horizontal part of the switchgear connector 1.

The end cap 12 may further comprise a flap 14, shown in FIG. 1, that protrudes from the end cap 12 in any radial direction 16 and provides a touch point for users to engage, when removing the end cap 12 from the switchgear connector 1. This way, the back plug 4 may be exchanged with another back plug 4, easily upgrading or swapping out the assembly. The end cap 12 may be used for grounding sensor parts and/or as a seal to protect from dirt, water or other substances from outside the switchgear connector 1. It is also possible for one embodiment to not comprise an end cap 12 and for the back plug to seal the switchgear connector 1.

The switchgear connector 1 further comprises a vertical part perpendicular to the horizontal part of the switchgear connector 1 that extends radially from the horizontal part of the switchgear connector 1. The vertical part may also be cylindrical and is located between the switchgear interface 2 and the back plug 4 within the switchgear connector 1. The vertical part is closer located to the end cap 12 than to the outside of the switchgear interface 2.

The horizontal part and the vertical part of the switchgear connector 1 may be integral, i.e. form a unitary piece. Between the switchgear interface 2 and the back plug 4, a switchgear lug 18 is located that extends radially into the vertical part of the switchgear connector 1 and that is further connected to an electrical cable 20. The switchgear lug 18 comprises a pin or, alternatively, a threaded bolt 22 that extends in both directions of the connection direction 6, towards the switchgear interface 2 and towards the back plug 4 and that is fastened with a nut 24.

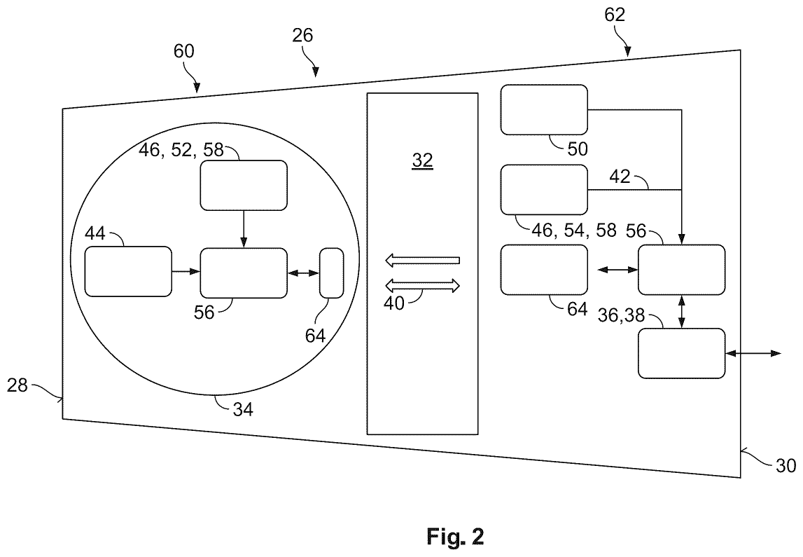

FIG. 2 shows a schematic diagram of a sensor assembly 26 that comprises a high voltage side 28 facing the switchgear and a low voltage side 30 on the opposite side. The sensor assembly 26 may be contained in the back plug 4. The sensor assembly 26 further comprises an isolation barrier 32 that electrically isolates the high voltage side 28 from the low voltage side 30. In FIG. 2, a sensor device 34 of the sensor assembly 26 is shown that may include at least one sensor to measure a physical quantity. The sensor device 34 is located on the high voltage side 28.

The sensor assembly 26 further comprises a data interface 36 that is located on the low voltage side 30. The data interface 36 of the sensor assembly 26 can be analog and/or digital. Having an analog data interface has the advantage of a low latency and an easy integration with sensors measuring data of the physical world, since many natural phenomena are continuous and analog. A digital data interface on the other hand is less susceptible to noise or interferences and allows for more flexibility. The combination of both combines both advantages and is more versatile, especially in retrofit situations.

The data interface 36 may comprise or consist of a field bus interface 38 that connects to an external data processing device and provides the sensor data 40 of the sensor device 34 to the external data processing device. The data interface 36 may also be a digital data interface. The sensor data 40 can be provided via wire, which provides higher speeds and a reliable transmission and is easy to set up. The sensor data 40 may be provided wirelessly, which reduces clutter, is quick and easy to install and allows for flexible and scalable set-ups. The data interface 36 may comprise wires and/or connectors to connect to the external data processing device.

The data interface 36 can be a bus system, especially a standardized bus system. The bus system can comprise a fieldbus, Ethernet or Bluetooth. Bus systems are simple and cost-effective to implement and have the advantage of uniformity, since the bus protocols and the unified connection technology and equipment are standardized, making expansions and changes easy and the system highly adjustable. Further, bus systems are easily scalable so that the number and type of devices attached to the bus systems may vary or be changed. The data interface 36 may further provide wires and/or connectors. The data interface 36 may be an in- and output interface, providing means to input sensor data as well as means to provide information or feedback to the user. The data interface 36 may also be used as an input interface to input programming, configurations and/or settings to the sensor assembly 26.

In this embodiment, the sensor assembly 26 also comprises a transmission path 42. This transmission path 42 may be located inside the isolation barrier 32. The transmission path 42 may be used to transfer sensor device data 40 between the sensor device 34 and the data interface 36. The transmission path 42 may be configured to provide unidirectional data transmission from the sensor device data 34 to the data interface 36, which is often used in real time monitoring or to secure the data transmission. In another embodiment, the data 40 obtained by the at least one sensor of the sensor device 34 can be transferred to the data interface 36, while configuration input by a user can be transferred from the data interface 36 to the sensor device 34, enabling bidirectional data transmission. Using data transmission from the data interface to the sensor device allows e.g. programming of the sensor device or the altering of parameters. The transmission path 42 may comprise a wireless section within the isolation barrier 32. The transmission path 42 may also be used to transmit power from the data interface 36 to the sensor device 34.

The sensor device 34 may comprise a temperature sensor 44 to measure temperature within the switchgear connector 1, as shown in FIG. 2. It may be configured to measure the temperature within the switchgear connector 1 to monitor if the maximum temperature threshold of the connector 1 is exceeded at any time. The sensor device 34 may also include a capacitive voltage sensor 46. Alternatively or cumulatively, the sensor device 34 may include at least one magnetic field sensor 48, a partial discharge sensor 50, a humidity sensor, an air pressure sensor or a line frequency sensor. The air pressure sensor and/or the humidity sensor, as well as any other type of sensor measuring ambient conditions, may be located on the low voltage side 30. The transmission path 42 may include any of the sensors, connecting any of the sensors to the data interface 36.

The humidity sensor can be configured to measure ambient humidity. It can also be configured to measure humidity within the back plug 4 or within the switchgear connector 1, which can prove important to monitor, since condensation on a part increases the risk of corrosion and failure. The transmission path 42 connects any of the sensors to the data interface 36.

Partial discharge often occurs within a solid insulation system and is not visible to the eye. Every partial discharge will degrade the component, such as the insulating material, further, increasing the risk of a cable system failure, making the monitoring of occurrences of partial discharges in connectors very beneficial in preventing such failures and elongating the operating life of the individual components.

The air pressure sensor, can be another preventive measure when identifying deviations of pressure within the connector 1.

The capacitive voltage sensor 46 may include a primary and secondary capacitor 52, 54, while the primary capacitor 52, or the passive part 52 of the capacitive voltage sensor 46, is located on the high voltage side 28 and the secondary capacitor 54, or the active part 54 of the capacitive voltage sensor 46, is located on the low voltage side 30. The isolation barrier 32 may be between the primary capacitor 52 and the secondary capacitor 54. In another embodiment, the isolation barrier 43 may also be part of the primary capacitor 52. The capacitive voltage sensor 46 may comprise a microcontroller 56 that uses the sensor device data 40, especially sensed by the temperature sensor 44, to execute a temperature correction for temperature compensation.

The combination of the capacitive voltage sensor 46 with the primary capacitor 52 and the secondary capacitor 54, the isolation barrier 32 and the microcontroller 56 as mentioned above may be a sensor subassembly 58, wherein the first sensor component 60 is located on the high voltage side 28 and the second sensor component 62 is located on the low voltage side 30 and wherein the first sensor component 60 and the second sensor component 62 measure one more physical quantity across the isolation barrier 32. The second sensor component 62 is connected to the transmission path 42 and outputs second sensor data 40.

This embodiment may prove useful when utilizing a sensor with an active and a passive part or one that requires both a high voltage and a low voltage. The at least one further physical quantity can be different from the at least one physical quantity measured by the sensor device 34, thus allowing for the measurement of at least two different physical quantities within one switchgear connector 1 for a versatile sensor being able to monitor multiple physical quantities within a connector 1.

The transmission path 42 may also be used to transmit power from the data interface 36 to the second sensor component. One or both of the sensor components 60, 62 may comprise a coil and may be used to measure a magnetic field. Coils provide a compact design, are easy to maintain and suitable for contactless sensing of, for example changes in magnetic fields. The first sensor component 60 can be a passive sensor component and the second sensor component 62 can be active sensor component. The second sensor component 62 can comprise a voltage sensor, a magnetic field sensor or a magnetic discharge sensor. The passive sensor has the advantage of a low power consumption and a reduced complexity in comparison to active sensors. The usage of passive sensors reduces the costs.

The first capacitor 52 and the second capacitor 54 can be made from the same material. The sensor subassembly 58 may include a reference capacitor 72 made of the same material as the primary capacitor 54 for higher accuracy and temperature measurements.

The sensor assembly 26 may comprise a voltage sensor 46, or part of a voltage sensor 46, at least one magnetic field sensor 48 to measure the current, and/or a partial discharge sensor 50. The sensors may be located on the low voltage side 30. The sensor assembly 26 may further comprise a data interface 36 on the low voltage side 30 to provide sensor data 40 and may further comprise a transmission path 42 that transmits the sensor data 40 from the second sensor component 62 to the output interface 36.

The second sensor component 62 can be configured to periodically output the data 40 for an efficient energy management. This allows the sensor assembly to conserve power by activating the communication at set intervals. This also reduces the overall data load, increases the predictability of data income and simplifies data processing. The second sensor component 62 may also be configured to output data 40 continuously, which has the advantage of real time monitoring and a faster response to anomalies.

The sensor assembly 26 may further comprise a first near field communication device 64 on the high voltage side 28. Another near field communication device 64 may be located on the low voltage side 30 with the isolation barrier 32 between the near field communication devices 64. The wireless communication and transmission happens between the two near field communication devices 64 across the isolation barrier 32. At least one of the near field communication devices 64 can be standardized under NFC standard. The wireless section may end at the first and the second near field communication device 64. Using the NFC standard enables short-range and contactless communication while providing quick data transfers. NFC devices can operate in both read and write modes, allowing for a bidirectional communication. They also have the advantage of not disturbing the isolation barrier 32 between the high voltage 28 side and the low voltage side 30.

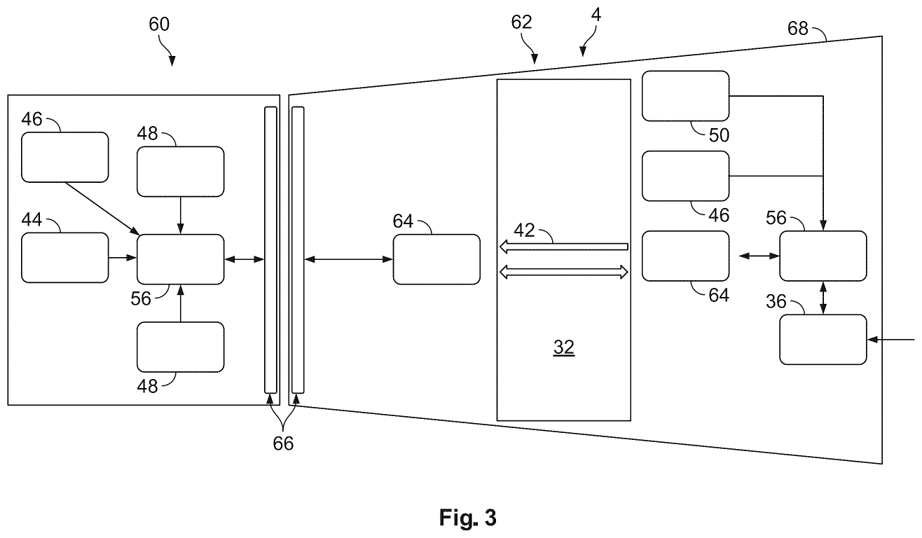

FIG. 3 shows another embodiment of the sensor assembly 26 where the first sensor component 60 is configured to be mounted on a switchgear lug 18. The switchgear lug 18, shown in FIG. 1, may comprise or consist of a busbar. The sensor device 34 or the first sensor component 60 may be configured to be mounted on a busbar.

The first sensor component 60 may comprise at least one, here two, magnetic field sensors 48 and a temperature sensor 44. The passive part of the voltage sensor 46 may also be located in the first sensor component 60. The sensors may be connected to a microcontroller 56. The components mentioned may be contained within one location, like a housing. They may also be directly mounted on the switchgear lug 18.

The first sensor component 60 may be installed in the switchgear connector 1 before the back plug 4. This is advantageous for the precise alignment of the first sensor component 60, as magnetic field sensors 48 are very position sensitive.

The first sensor component 60 and the back plug 4 may be connected through a mechanically separable electrical connection 66 on the high voltage side 28. In this embodiment, the mechanically separable electrical connection 66 connects the near field communication device 64 of the high voltage side 28 to the sensor component 60 of the high voltage side 28. The mechanically separable electrical connection 66 may be slip rings or electrical connectors that are mated. One part of the mechanically separable electrical connection 66 may be contained in the back plug, while the other may be located within the first sensor component 60.

The isolation barrier 32 may be located within the back plug 4. The first near field communication device 64 of the high voltage side 28 may be located in the back plug 4. The first near field communication device 64 may be arranged closely to the isolation barrier 32 and may be connected via the transmission path 42 and the mechanically separable electrical connection 66 to the first sensor component 60.

The back plug 4 may contain the second sensor component 62 and the low voltage side 30, the second near field communication device 64 and the data interface 36. The data interface 36 may be used to output the sensor data 40 to an external data processing device. The back plug 4 may comprise a housing 68. The housing 68 may contain the low voltage side 28 and the isolation barrier 32, while the rest of the sensor assembly 26 can be outside of the back plug 4.

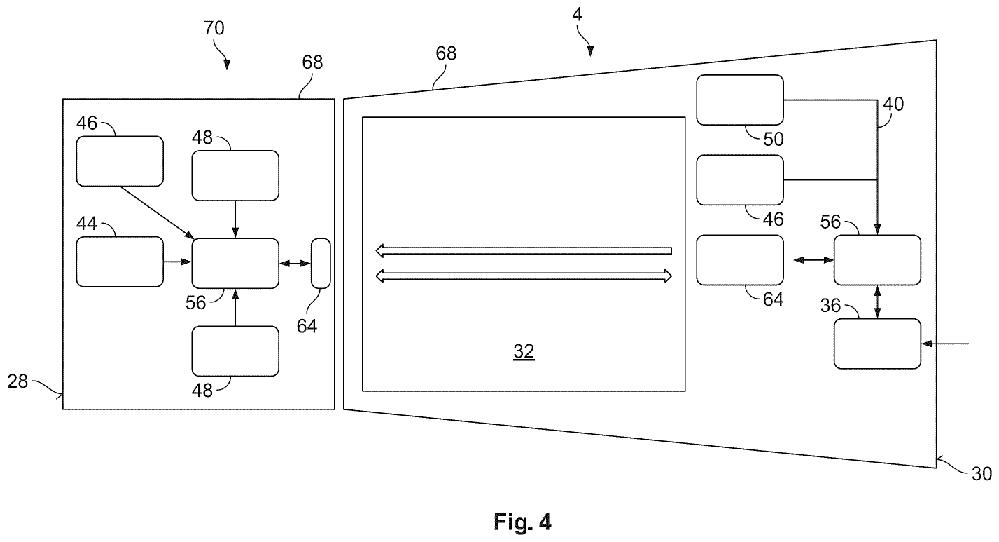

FIG. 4 shows another embodiment, wherein the high voltage side 28 and the low voltage side 30 are physically separated, for example contained in two different housings 68. On the high voltage side 28 the sensor assembly 26 may comprise a microcontroller 56 that obtains sensor data 40 of different sensors. This is especially advantageous for the position sensitive magnetic field sensor, since one can ensure the ideal alignment with the installation of the back plug 4 before adding the less sensitive components of the sensor assembly 26 to the switchgear connector 1.

In this embodiment, the high voltage side 28 comprises a temperature sensor 44, two magnetic field sensors 48 and the passive part of the voltage sensor 46. It is also conceivable to add or switch the sensors to a humidity sensor, a line frequency sensor and/or a partial discharge sensor. As the frequency of an electrical system varies, for example when load and generation of power change, monitoring the line frequency proves useful to take protective steps, i.e. targeted switching-off of components of a network when a decline of frequency is sensed.

The high voltage side 28 may further comprise the first near field communication device 64 that is connected to the microcontroller 56 and located on the side facing the back plug 4. The first near field communication device 64 may communicate wirelessly across the isolation barrier 32 with the second near field communication device 64 that may be contained in the back plug 4 and that is located on the low voltage side 30 of the sensor assembly 26.

The back plug 4 may contain the isolation barrier 32 that provides a galvanic isolation between the high voltage side 28 and the low voltage side 30. The second near field communication device 64 can be located close to the isolation barrier 32 in the direction of connection 6, enabling the sending and receiving data to the first near field communication device 64. The second near field communication device 64 may be connected to a microcontroller 56. This microcontroller 56 obtains data 40 from a partial discharge sensor 50 and an active part of the voltage sensor 46 and further communicates with a data interface 36 that may be connected externally to another device or interface to provide sensor data 40, which allows for remote accessing of obtained data and the possibility to react quickly to deviations in data. In another embodiment, the high voltage side 28 of the sensor assembly 26 is completely contained in the back plug 4.

Another embodiment of the invention is a set for switchgear connector 1 that comprises the back plug 4 and a sensor unit 70 that may be mounted on a switchgear lug 18 on the high voltage side 28. The sensor unit 70 may comprise the sensor device 34 and the first sensor component 60. The sensor unit 70 may comprise only one of the sensor device 34 or the first sensor component 60. It is also possible for the sensor unit 70 to comprise the first near field communication device 64. In that case, the back plug 4 may comprise the second near field communication device 64. The sensor unit 70 may be connected via the mechanically separable electrical connection 66 and may contain a part of the mechanically separable electrical connection 66, while the back plug 4 may contain the other part of the mechanically separable electrical connection 66. The embodiment may be a retrofit set and may be used to upgrade any sensors or components.

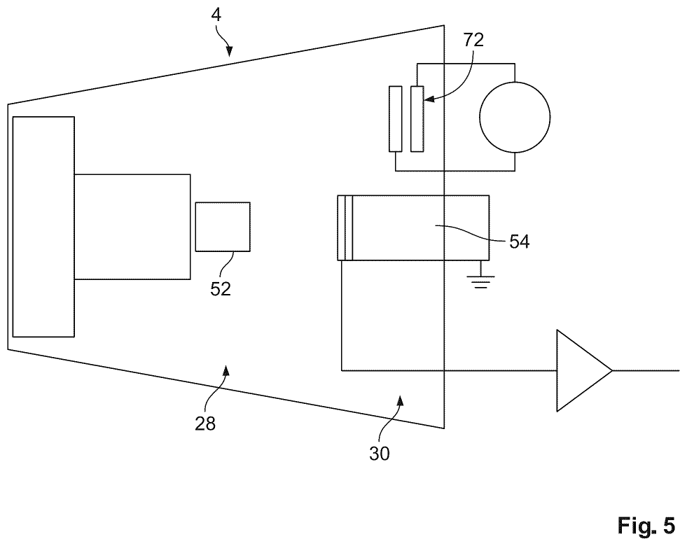

FIG. 5 shows a schematic diagram of the capacitive voltage sensor 46, which may comprise an active voltage divider that may use an amplifier to measure very low signals. The capacitive voltage sensor 46 may comprise a capacitive divider with the primary capacitor 52 and the secondary capacitor 54 connected in series. The primary capacitor 52 is located on the high voltage side 28. The secondary capacitor 54 is located on the low voltage side 30. With this combination, the capacitive voltage sensor 46 does not need an active part on the high voltage side 28. The primary capacitor 52 and the secondary capacitor 54 may be formed by the same dielectric and located close to each other to achieve a high accuracy in sensing. The capacitive voltage sensor 46 can be temperature-compensated and can include a reference capacitor made of the same material as the primary capacitor 52 to reduce the effect of temperature fluctuations on the components of the sensor. The secondary capacitor 54 may alternatively or cumulatively have a reference capacitor 72 that is formed by the same material as the primary capacitor 54 that can be used for temperature compensation. The secondary capacitor 54 may also be formed of a different material than the primary capacitor 54. In particular, the secondary capacitor 54 may be manufactured from commercially available components. The voltage sensor 46 may also use a component of the sensor data representative of temperature for temperature compensation.

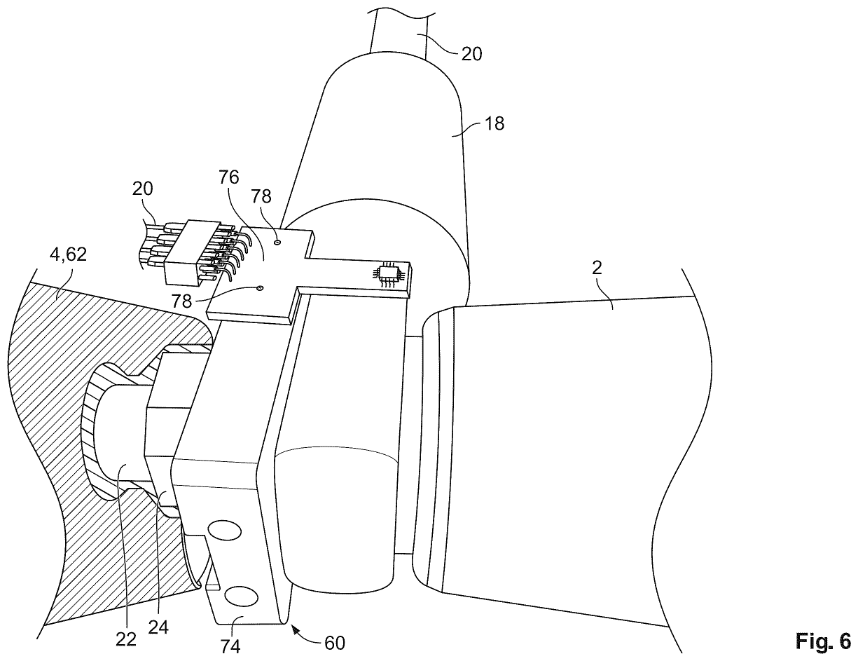

In FIG. 6, the switchgear connector 1 is shown with a switchgear lug 18 and a back plug 4. In this embodiment, the sensor assembly 26 comprises two parts, for example the first sensor component 60 and the second sensor component 62. While one part, such as the second sensor component 62, may be contained in the back plug 4, the other part may be the first sensor component 60 configured to be mounted on the switchgear lug 18.

The first sensor component 60 may comprise a mounting plate 74, where at least one sensor 76, for example a temperature sensor 44, may be attached to the mounting plate 74 and wherein the at least one sensor 76 protrudes in the direction of connection 6 in a way that allows the sensor 76 to be close enough and/or touch the switchgear lug 18 to measure a physical quantity on the switchgear lug 18.

The first sensor component 60 may also comprise of two or more sensors 76. The two or more sensors 76 may comprise at least one magnetic field sensors 48 configured to measure the magnetic field to determine the current.

The mounting plate 74 may comprise a mounting hole through which the threaded bolt 22 may be fed through to attach the mounting plate 74 to the switchgear lug 18. The nut 24 may then be used to fix the mounting plate 74 to the switchgear lug 18. The sensor 76 may be fastened to the mounting plate via screws 78 or other fasteners.

The above solutions are advantageous, as they facilitate monitoring the condition of switchgear connectors for protective and maintenance purposes and help avoid fatal faults and damages during operation and maintenance. Thus, a sudden and unexpected failure of the switchgear connectors can be avoided and the switchgear connectors perform more reliably.

Moreover, the solutions may be used to retrofit existing switchgear connectors. Thus they can be used to modernize existing switchgear installations, so that they can be used more efficiently and more reliably in smart power systems.

1. A sensor assembly for a switchgear connector, the sensor assembly comprising:
a high voltage side facing a switchgear;
a low voltage side;
an isolation barrier that provides a galvanic isolation between the high voltage side and the low voltage side;
a sensor device measuring at least one physical quantity and outputting a sensor data representative of the at least one physical quantity, the sensor device is arranged on the high voltage side;
a data interface arranged on the low voltage side and providing for the sensor data to be accessible from outside of the sensor assembly; and
a transmission path transferring the sensor data between the sensor device and the data interface, the transmission path has a wireless section extending across the isolation barrier.

2. The sensor assembly of claim 1, further comprising a sensor subassembly including a first sensor component on the high voltage side and a second sensor component on the low voltage side, the first sensor component and the second sensor component cooperatively measure at least one further physical quantity.

3. The sensor assembly of claim 2, wherein the second sensor component is connected to the transmission path and outputs a second sensor data representative of the at least one further physical quantity.

4. The sensor assembly of claim 2, wherein the first sensor component is a passive sensor component and the second sensor component is an active sensor component.

5. The sensor assembly of claim 2, wherein the first sensor component is mounted on a switchgear lug.

6. The sensor assembly of claim 1, further comprising a first near field communication device on the high voltage side and a second near field communication device on the low voltage side.

7. The sensor assembly of claim 6, wherein the wireless section extends between the first near field communication device and the second near field communication device.

8. The sensor assembly of claim 1, wherein the wireless section transmits power from the data interface to the sensor device.

9. The sensor assembly of claim 1, wherein the transmission path has a mechanically separable electrical connection on the high voltage side.

10. The sensor assembly of claim 1, wherein the low voltage side is contained in a back plug.

11. The sensor assembly of claim 10, wherein the isolation barrier is contained in the back plug.

12. The sensor assembly of claim 11, further comprising a first near field communication device contained in the back plug and a second near field communication device on the low voltage side.

13. The sensor assembly of claim 11, wherein the high voltage side is contained in the back plug.

14. The sensor assembly of claim 11, further comprising a sensor unit mounted on a switchgear lug on the high voltage side.

15. The sensor assembly of claim 14, wherein the sensor unit has a first near field communication device and a second near field communication device is disposed in the back plug.

16. A sensor assembly for a switchgear connector, the sensor assembly comprising:
a high voltage side facing a switchgear;
a low voltage side;
an isolation barrier that provides a galvanic isolation between the high voltage side and the low voltage side;
a sensor subassembly including a first sensor component on the high voltage side and a second sensor component on the low voltage side, the first sensor component and the second sensor component cooperatively ensure at least one physical quantity across the isolation barrier, the second sensor component outputs a sensor data representative of the at least one physical quantity;
a data interface arranged on the low voltage side and providing the sensor data to be accessible from outside the sensor assembly; and
a transmission path transmitting the sensor data from the second sensor component to the date interface.

17. The sensor assembly of claim 16, further comprising a sensor device measuring at least one further physical quantity and outputting a second sensor data representative of the at least one further physical quantity, the sensor device is arranged on the high voltage side.

18. The sensor assembly of claim 17, wherein the transmission path connects the sensor device to the data interface and has a wireless section extending across the isolation barrier.

19. A back plug for a switchgear connector, comprising:
a low voltage side;
an isolation barrier that provides a galvanic isolation between a high voltage side and the low voltage side; and
a data interface providing for a sensor data representative of at least one physical quantity measured by a sensor device to be accessible from outside the back plug.

20. The back plug of claim 19, further comprising the high voltage side, the sensor device, and a transmission path transferring the sensor data between the sensor device and the data interface.
